(19) United States
(12) Patent Application Publication
(10) Pub. No.: US 2019/0157508 A1
(43) Pub. Date: May 23, 2019

(54) LIGHT-EMITTING DIODES (LEDS) WITH MONOLITHICALLY-INTEGRATED PHOTODETECTORS FOR IN SITU REAL-TIME INTENSITY MONITORING

(71) Applicant: The University of Hong Kong, Hong Kong (CN)

(72) Inventors: Hoi Wai CHOI, Hong Kong (CN); Kwai Hei LI, Hong Kong (CN); Haitao LU, Hong Kong (CN)

(73) Assignee: The University of Hong Kong, Hong Kong (CN)

(21) Appl. No.: 16/300,329

(22) PCT Filed: May 17, 2016
(86) PCT No.: PCT/CN2016/082320

§ 371 Date: Nov. 9, 2018

(51) Int. Cl. H01L 33/24; H01L 27/30; G09G 3/32

(52) U.S. Cl. CPC H01L 33/24; G09G 3/32; H01L 27/305

(57) ABSTRACT

A device includes a light-emitting diode (LED) integrated with a photodetector on the same semiconductor platform, such that the photocurrent generated by the photodetector can be used to monitor the optical output of the LED, which is located adjacent to the photodetector. The device provides a compact, robust, reliable and low-cost way of monitoring LED emission.

### CROSS-REFERENCE TO RELATED APPLICATIONS

This application is a U.S. National Phase application under 35 U.S.C. § 371 of International Application No. PCT/CN2016/082320, filed on May 17, 2016, which is incorporated herein by reference in its entirety. The International Application was published in English on Nov. 23, 2017 as WO 2017/197576 A1 under PCT Article 21(2).

### FIELD

The subject matter disclosed herein relates to light-emitting diode (LED) devices.

### BACKGROUND

Performance of solid-state lighting devices has improved tremendously in recent years, owing to the development of light-emitting diodes (LEDs) with high luminous efficacy and long lifetime. However, gradual decline of the intensity of LED output is as inevitable as it was for earlier generations of lighting devices, albeit at a much slower rate.

Specifically, the degradation mechanisms of LEDs are highly temperature-dependent, as elevated junction temperature will cause reduction in light output and thus acceleration in chip degradation. Furthermore, individual LEDs within a light source can exhibit varying degradation rates even when they are subjected to the same environmental factors. Such long-term drift in light output poses one of the most significant challenges in lighting applications typically comprising a plurality of LEDs such as, for example, residential lamps and outdoor displays. In some instances, LED-based lighting devices do not generate sufficient brightness or emission uniformity, leading to a much shorter lifespan than the manufacturer-determined expectancy. Due to the intrinsically large divergence angles created by LED emission, the overall emission pattern of an LED-based lighting device is a combination of overlapping emission cones from a plurality of LEDs, as illustrated in FIG. 1. As a result, discrete intensity variation from individual LEDs will cause non-uniformity in the overall emission pattern.

Apart from the aforementioned general lighting devices, other LED-based applications, such as fiber light source and indoor agricultural and greenhouse lighting, may require the light source to be highly stable (i.e., without intensity drift in individual LEDs) against short-term environmental variations caused by factors including electrostatic breakdown, electrode deterioration, and other thermal- and humidity-related issues. One method of monitoring intensity variations in a plurality of LEDs' output is to provide a separate photodetector pointing toward the LEDs at a specific angle (FIG. 1).

Although a number of semiconductor photodetectors such as Schottky barrier photodiodes, p-n, p-i-n, metal-semiconductor-metal (MSM), metal-insulator-semiconductor (MIS), and high-electron-mobility transistor (HFET) sensors, have been made available for this purpose, the off-chip integration of a photodetector together with chip carrier packages above the light source requires the use of several bulky mechanical components to maintain the detecting angle of the photodetector, leading to reduced light output and non-uniform emission. Integrating tedious photodetector configurations onto LED light sources having narrow divergence angles can be especially challenging.

Additionally, the existing solutions are only effective at a single position and/or an angle and thus unable to detect the intensity changes from a plurality of individual LEDs. Moreover, the entire off-chip system may be sensitive to other unexpected environmental factors, such as shocks or vibration, potentially reducing the reliability of the overall device.

### SUMMARY

In an exemplary embodiment, the invention provides a light-emitting diode device. The light-emitting device comprises: a light-emitting diode, configured to emit light; and a photodetector, configured to receive light emitted by the light-emitting diode and to generate a current corresponding to emission intensity of the light-emitting diode. The light-emitting diode and the photodetector are disposed in a same layer of the light-emitting diode device corresponding to a single semiconductor platform.

In another exemplary embodiment, the invention provides a device, comprising a plurality of light-emitting diode devices. Each light-emitting diode device comprises: a light-emitting diode, configured to emit light; and a photodetector, configured to receive light emitted by the light-emitting diode and to generate a current corresponding to emission intensity of the light-emitting diode. The light-emitting diode and the photodetector are disposed in a same layer of the light-emitting diode device corresponding to a single semiconductor platform.

In yet another exemplary embodiment, the invention provides a method of fabricating a light-emitting diode device, the method comprising: depositing an n-type semiconductor layer on a top surface of a substrate; depositing an active layer on the n-type semiconductor layer, the active layer comprising a plurality of quantum wells; depositing a p-type semiconductor layer on the active layer; etching the n-type semiconductor, active, and p-type semiconductor layers to form trenches between a light-emitting diode and a photodetector, wherein the light-emitting diode and the photodetector are electrically isolated from one another by the trenches.

### BRIEF DESCRIPTION OF THE DRAWINGS

The invention will be described in even greater detail below based on the exemplary figures. The invention is not limited to the exemplary embodiments. All features described and/or illustrated herein can be used alone or combined in different combinations in embodiments of the invention. The features and advantages of various embodiments of the invention will become apparent by reading the following detailed description with reference to the attached drawings, which illustrate the following:

FIG. 1 is a schematic diagram illustrating an exemplary embodiment of an LED array with an off-chip photodetector.

FIG. 2 is a schematic diagram depicting a photolithography process for fabricating a monolithically integrated LED-photodetector device according to an exemplary embodiment of the invention. Part (a) of FIG. 2 illustrates the starting LED wafer coated with an ITO layer. Part (b) of FIG. 2 illustrates the result of the mesa definition and ICP etching. Part (c) of FIG. 2 shows the metal pad coating deposited by E-beam evaporation. Part (d) of FIG. 2 illustrates the separation between the LED and the photodetector.

FIG. 3 is a schematic diagram illustrating various angles at which light beams may travel within the LED, the sapphire substrate, and the photodetector according to an exemplary embodiment of the invention.

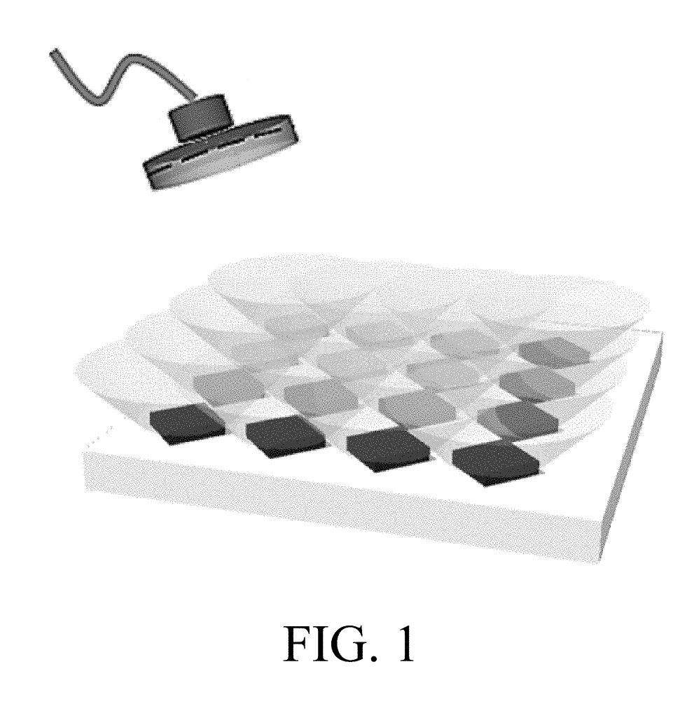

Part (a) of FIG. 4 is a microphotograph of an operating integrated LED-photodetector device according to an exemplary embodiment of the invention.

Part (b) of FIG. 4 illustrates an electroluminescence (EL) spectrum (the line with the peak near the center of the plot) and spectral responsivity (the squares that begin near the top, left-hand side of the plot) of the on-chip photodetector of a device according to an exemplary embodiment of the invention.

Part (a) of FIG. 5 is a plot illustrating the I-V characteristics of an exemplary on-chip photodetector integrated with an LED measured in darkness and illumination, respectively.

Part (b) of FIG. 5 is a plot of light output power (the line that is higher as depicted, having the square plot points) and photocurrent (the line that is lower as depicted, having the circular plot points) as a function of the operation time of an exemplary device.

Part (c) of FIG. 5 is a plot of photocurrent (amps) versus LED current (milliamps).

Parts (a) and (b) of FIG. 6 are microphotographs of a device, according to an exemplary embodiment of the invention, whose surface is deposited with phosphors.

Part (c) of FIG. 6 shows an EL spectrum of a packaged device with phosphors according to an exemplary embodiment of the invention.

FIG. 7 depicts schematic diagrams of red-, green-, and blue-light emitting diodes with monolithically integrated on-chip photodetectors arranged in a multi-chip configuration (part (a) of FIG. 7) and a chip-stacking configuration (part (b) of FIG. 7). As depicted in part (a) of FIG. 7, the blue LED is the left-most, the green LED is the top-most, and the red LED is the right-most. As depicted in part (b) of FIG. 7, the blue LED is on the top, the green LED is under the blue LED, and the red LED is under the green LED.

FIG. 8 shows a monolithically integrated LED-photodetector device, according to an exemplary embodiment of the invention, comprising a GaN-based semiconductor platform.

FIG. 9 shows a plot of photocurrent (amps) versus voltage (volts).

Parts (a) and (b) of FIG. 10 are schematic diagrams of red-, green-, and blue-light emitting micro-displays with monolithically-integrated photodetectors arranged in a multi-chip configuration (part (a) of FIG. 10) and a chip-stacking configuration (part (b) of FIG. 10) configuration, respectively. As depicted in part (a) of FIG. 10, starting with the top-most LED as depicted, the first left-to-right line shows red LEDs, the next line below that shows green LEDs, followed by blue, red, green, and blue LEDs, in that order. As depicted in part (b) of FIG. 10, an array of blue LEDs is on the top, a green LED array is under the blue LED array, and a red LED array is under the green LED array.

FIG. 11a shows a plot of voltage (V) versus current (mA); FIG. 11b shows a plot of EL intensity (a.u.) versus wavelength (nm); and FIG. 11e shows a plot of spectral width (nm) versus current (mA).

### DETAILED DESCRIPTION

Exemplary embodiments of the invention provide integrated light-emitting diode (LED) devices whose output can be effectively monitored by photodetectors. Exemplary embodiments of the invention provide devices directed to LED lighting applications and methods of fabricating the same. In some embodiments, a device can comprise an LED integrated with a photodetector on the same semiconductor platform, such that the photocurrent generated by the photodetector can be used to monitor the optical output of the LED, which is located adjacent to the photodetector. Advantageously, exemplary embodiments of the invention are able to provide compact, robust, and reliable photodetectors capable of monitoring LED emission via a low-cost approach.

In an exemplary embodiment, an electronic device can include an LED and a photodetector integrated onto a single semiconductor platform and positioned adjacent to each other, and the current generated by the photodetector can be used to monitor the optical output of the LED. The LED diode and the photodetector can be monolithically fabricated onto the single semiconductor platform.

In another exemplary embodiment, a method of fabricating an electronic device can include: depositing an n-type semiconductor layer on a top surface of a substrate having a coating on a bottom surface thereof; depositing an active layer on the substrate, the active layer comprising a plurality of quantum wells; depositing a p-type semiconductor layer on the active layer; depositing a current spreading layer on the active layer; depositing a layer of photoresist on the current spreading layer; masking the layer of photoresist according to a pre-defined pattern defining the size and location of an LED to be formed and the size and location a photodetector to be formed; exposing the masked photoresist to UV light; developing the UV-exposed surface of the electronic device in a bath of photoresist developer to form the LED and the photodetector; and etching away unmasked regions on the surface to form contact pads and trenches configured to provide electrical isolation between the LED and the photodetector.

Exemplary embodiments of the invention provide devices directed to light-emitting diode (LED) lighting applications and methods of fabricating the same. In some embodiments, a device can comprise an LED integrated with a photodetector on the same semiconductor platform, such that the photocurrent generated by the photodetector can be used to monitor the optical output of the LED, which is located adjacent to the photodetector. Advantageously, exemplary embodiments of the invention are able to provide compact, robust, and reliable photodetectors capable of monitoring LED emission via a low-cost approach.

In some embodiments, the LED and the photodetector have the same semiconductor structure. Because luminesce and absorption are complementary processes, an LED that is intended for light emission can also function as a photodetector in which electron-hole pairs are generated by optical absorption, producing a substantial photocurrent flow between electrodes. By defining a region of the device as a photodetector, the generated photo current can be utilized for monitoring the optical output of the LED located on the same device.

In some embodiments, the LED and the photodetector are co-fabricated as a unit by a single set of micro-fabrication procedures rather than being constructed separately. This monolithic integration approach, as an alternative to the conventional external integration approach, is an attractive manufacturing strategy due to its use of smaller circuit boards, fewer discrete components, and reduced manufacturing cost.

Advantageously, the monolithic integration methods disclosed herein can improve the overall device performance by reducing the size of the photodetector and allowing the components (e.g., the LED and the photodetector) to be placed in close proximity to each other, thereby maximizing the effect of optical coupling between the LED and the photodetector. Furthermore, the monolithic fabrication process provided herein utilize much less material than if the device were fabricated in discrete steps. In an exemplary embodiment, an LED and a photodetector having identical (or similar) structure as the LED are co-fabricated on the same semiconductor platform comprising, e.g., GaN-on-sapphire, using a single set of photolithography procedures.

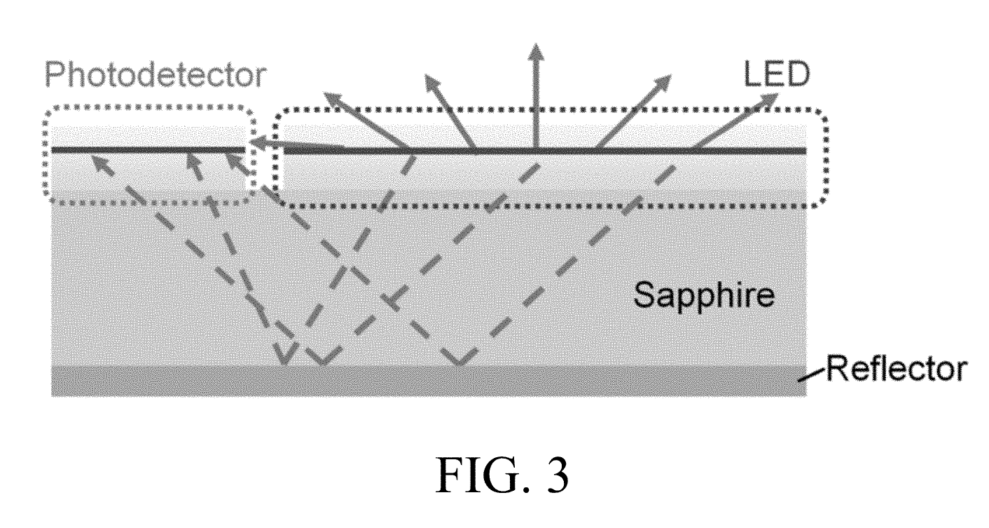

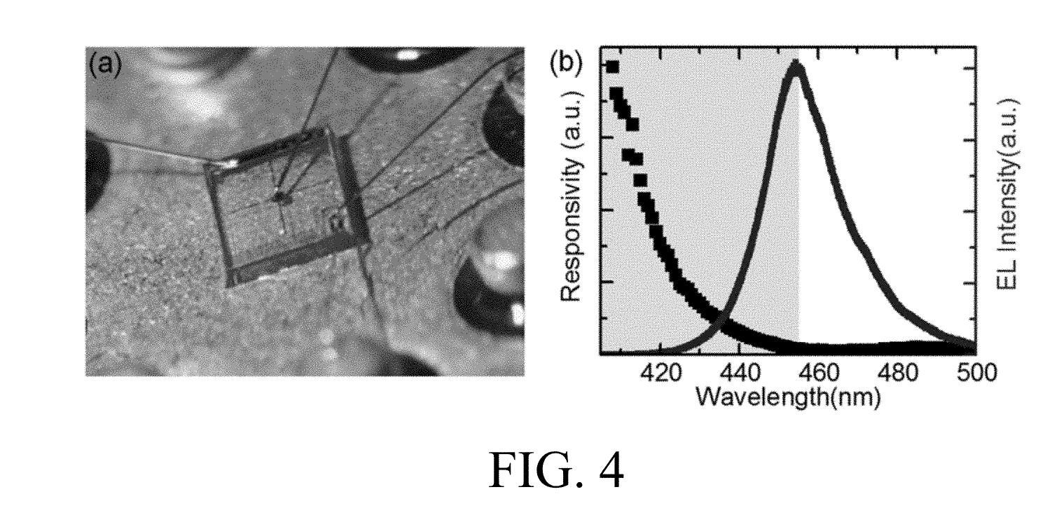

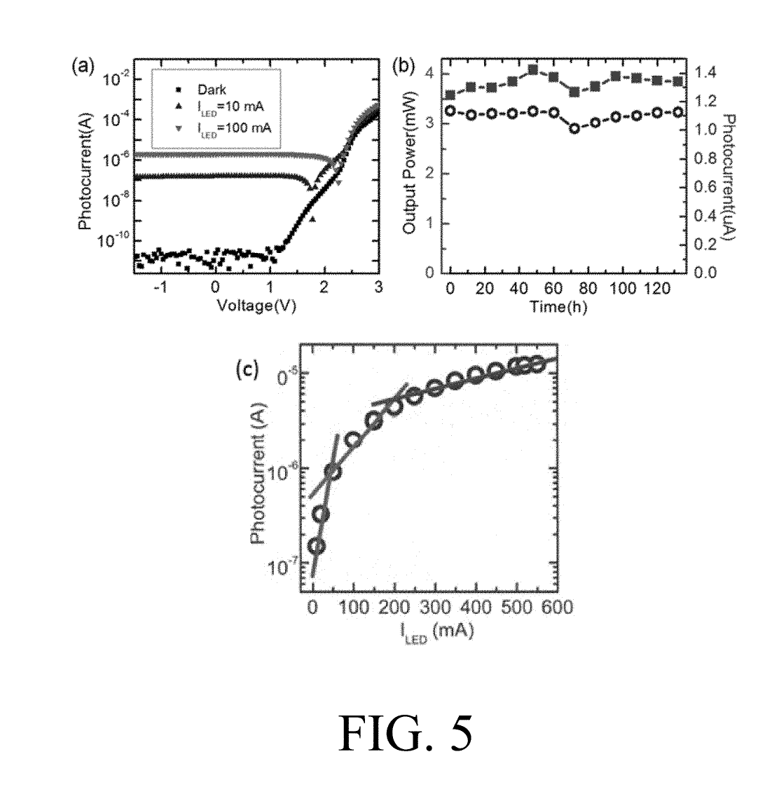

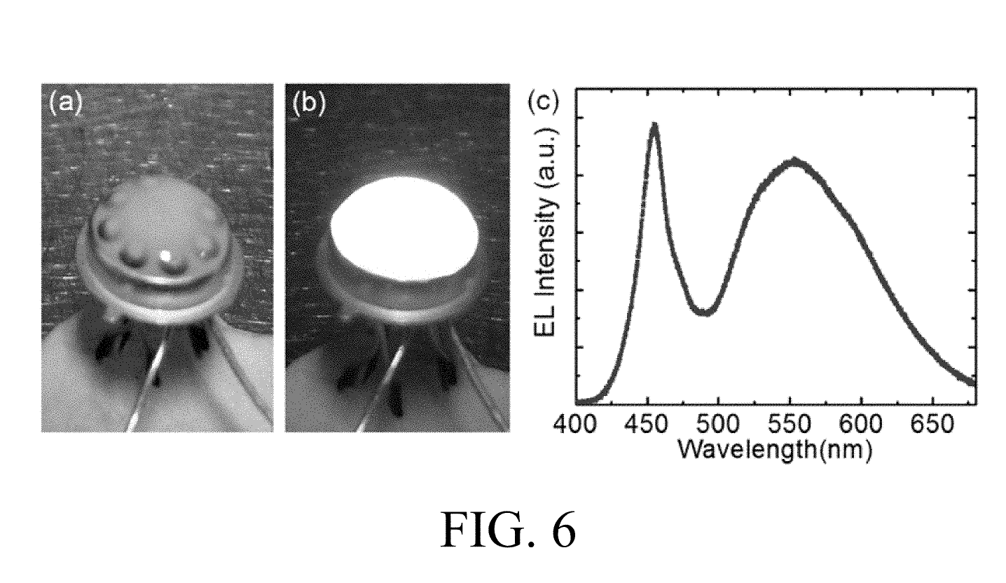

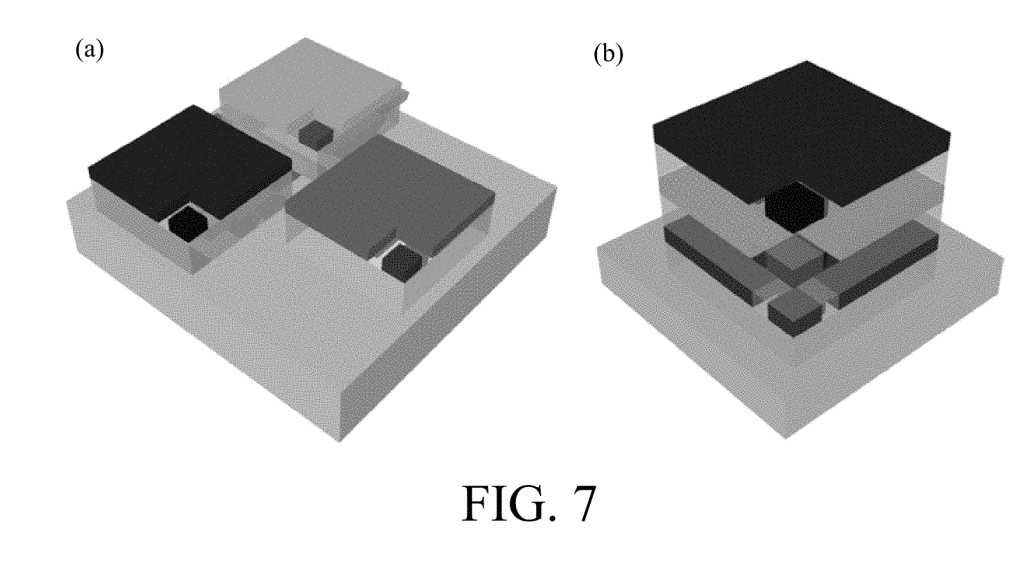

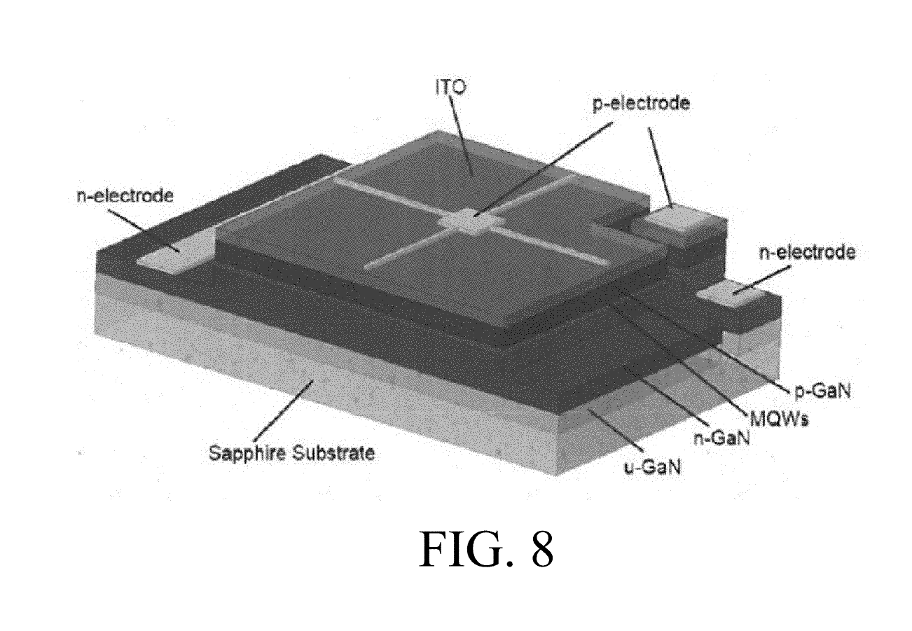

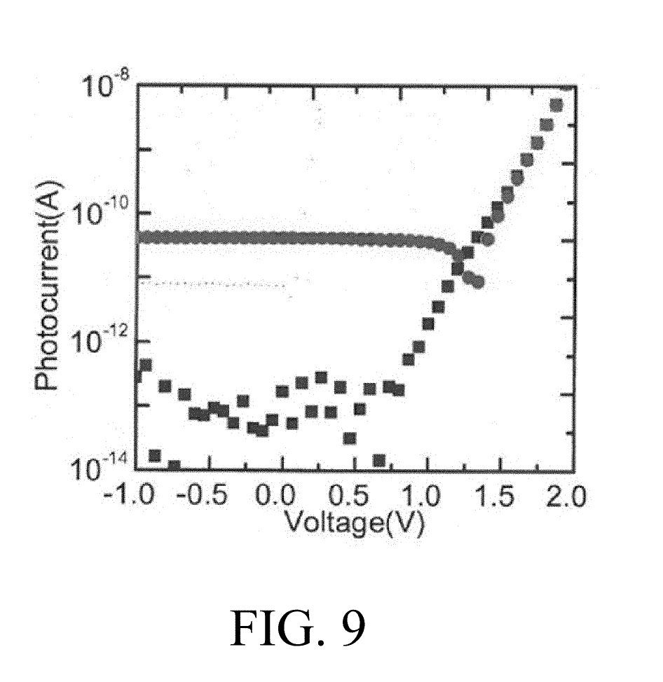

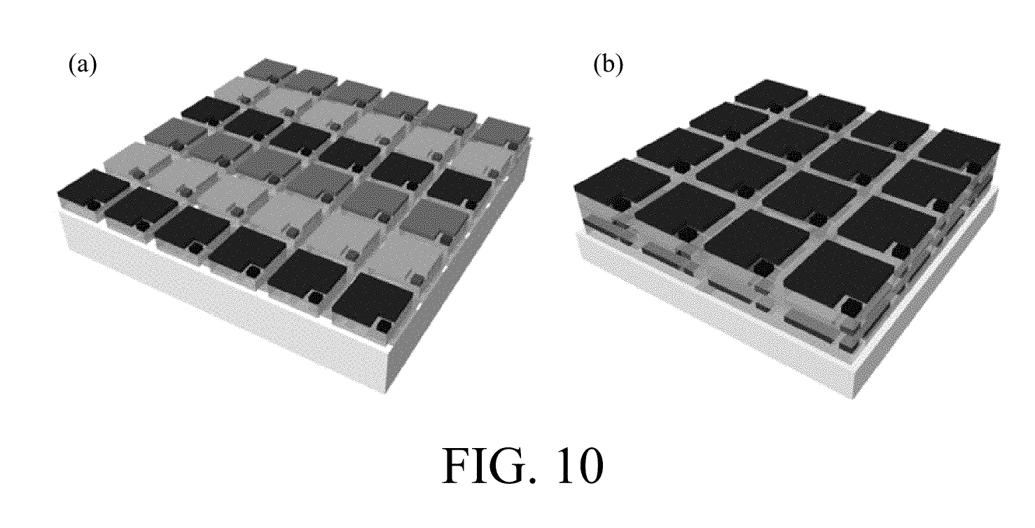

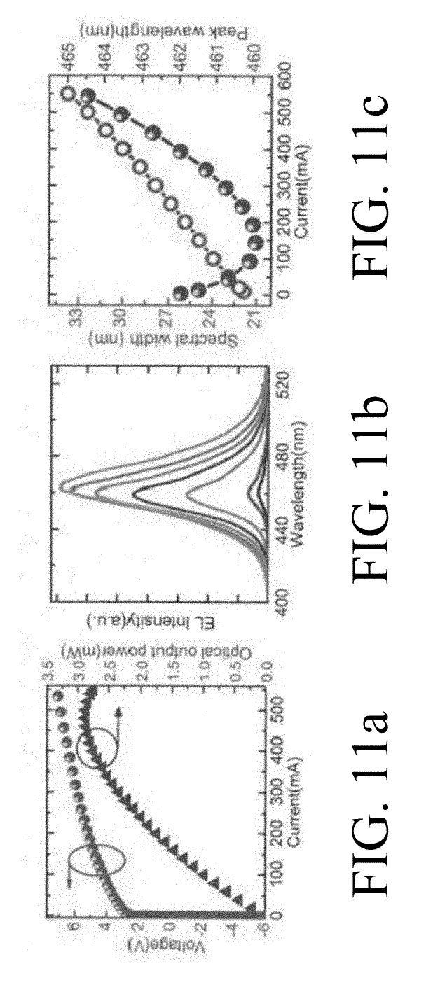

According to some embodiments of the invention, the ability for a photodetector located adjacent to an LED on the same platform to detect optical output of the LED is attributed to a light coupling mechanism involving two distinct processes (FIG. 3). First, the side-by-side, i.e., planar, configuration allows light emitted from the LED's etched sidewall to directly irradiate the nearby photodetector. The upward emitting light from the LED, on the other hand, is extracted from the device into free space and would not be detected by the planar photodetector located adjacent to the LED. Second, a transparent substrate, such as sapphire, can serve as a waveguide that allows a constant portion of the downward-emitting light to propagate toward the photodetector. The photodetector subsequently converts the light signal into measurable photocurrent signal. Advantageously, with the photocurrent data as the feedback signal monitoring the light intensity level of the LED, any signal drifts in the diode can be corrected for efficiency, ensuring precise monitoring of the long-term and short-term performance of the LED device.

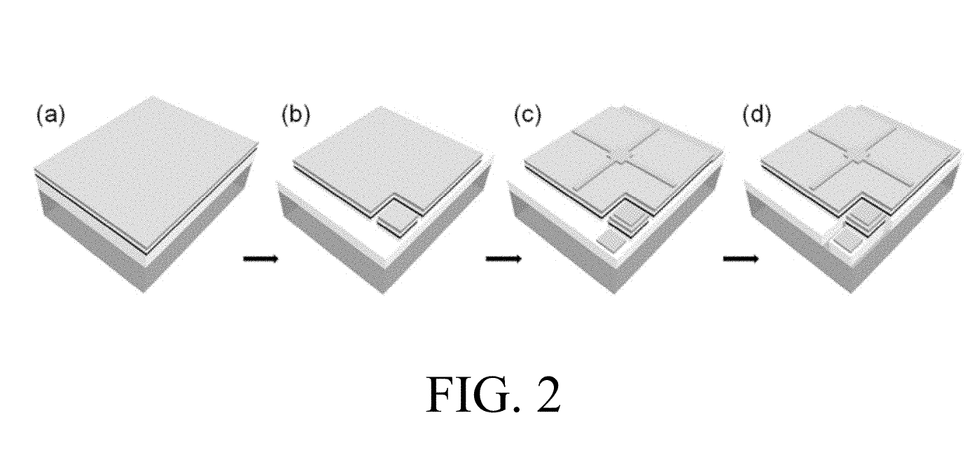

In some embodiments, the integrated device comprising an LED and an adjacently located photodetector can be fabricated monolithically using standard micro-fabrication procedures, including, inter alia, photolithography, etching, and metal deposition. In some embodiments, layer deposition can be accomplished using thermal evaporation, sputtering, electron beam evaporation, or a combination thereof. FIG. 2 depicts schematic diagrams demonstrating an exemplary set of procedures in which a GaN-on-sapphire platform is used to fabricate an integrated device according to an embodiment of the invention. An illustration of the finished device is shown in FIG. 8.

Referring to part (a) of FIG. 2, the GaN-based platform can be grown by, for example, metal organic chemical vapor deposition (MOCVD) on a transparent sapphire substrate. The resulting GaN-based LED structure can include an n-type GaN layer, an active layer comprising multiple quantum wells, and a p-type GaN layer sequentially deposited onto the substrate, though embodiments are not limited thereto. A transparent current spreading layer comprising, for example, Ni/Au or indium-tin-oxide (ITO), can be deposited on top of the p-type GaN layer to ensure uniform light emission over the surface of the device (see, for example, FIG. 8).

In some embodiments, the bottom surface of the GaN-based platform comprises a reflective coating, which may be, for example, silver, aluminum, or a distributed Bragg reflector (DBR). In an exemplary embodiment, the coating comprises a DBR. A DBR, relying on pairs of alternating dielectric materials having different refractive indices, comprise a wavelength-selective mirror that reflects light of certain wavelengths within a reflectance band and transmits light of different wavelengths within the transmission band. The characteristics of the DBR depend on design parameters such as, for example, choice of dielectric materials and their respective thicknesses.

Part (b) of FIG. 2 illustrates a layer of photoresist being spin-coated onto the current spreading layer, which is then exposed to UV light through a photo-mask comprising a pre-defined pattern defining the boundaries of the mesa of the various components of the integrated device. A mesa, as used herein, denotes a region on the device surface having distinct boundaries defining a specific component of the device.

In some embodiments, the UV-exposed surface of the device can be developed in a bath of photoresist developer. After development, the photoresist pattern can be hard baked at a temperature, for example, in a range of between about 115° C. and about 170° C. for a duration, for example, of about 3 minutes to about 10 minutes. In an exemplary embodiment, the photoresist pattern can be hard baked, for example, at approximately 120° C. for about 5 minutes. The uncoated regions of GaN can be etched away until the underlying n-type layer is exposed. In some embodiments, the etching can be achieved by a number of methods including, but not limited to, plasma etching, ion etching, and laser etching.

In some embodiments, the photoresist pattern can be used to expose areas of the p-type and n-type contact pads, shown as the p-electrodes and n-electrodes, respectively, in FIG. 8, using another photolithography process. Specifically, a bi-layer structure comprising, for example, Ti/Au and/or Ni/Au can be deposited by electron beam (E-beam) evaporation and lifted off in a bath (e.g., an acetone bath). Contacts can be subjected to rapid thermal annealing (RTA) at a temperature, for example, in a range of between about 450° C. and about 600° C. for a duration, for example, of about 5 minutes to about 10 minutes. In an exemplary embodiment, the RTA can be carried out, for example, at about 550° C. for about 5 minutes in nitrogen ambient and/or oxygen ambient.

A selective etching process can subsequently be carried out to form trenches for electrical isolation between the contact pads of the LED and the photodetector, respectively. The selective etching of the GaN epilayer over sapphire may be achieved using a plasma etching or pulsed laser etching method (part (d) of FIG. 2). Each individual integrated LED-photodetector chip can be diced by laser machining and/or a diamond dicing saw.

The sidewalls of mesas of the LED and photodetector may be passivated by insulating materials such as, e.g., silicon dioxide or aluminum oxide, though embodiments of the invention are not limited thereto. A layer of oxide can be coated over the entire surface using, for example, electron beam evaporation, plasma-enhanced chemical vapor deposition (PECVD), or atomic layer deposition (ALD) (part (c) of FIG. 2).

In some embodiments, the integrated LED-photodetector chip can be bonded to a transistor outline (TO) metal can package using an adhesive (e.g., acrylics and epoxies), and bond pads can be connected to the package by wire bonding. Four wire-bonds may be utilized to establish electrical connection to the chips, including the p- and n-pads of the LED and photodetector.

In some embodiments, the surface area of the LED is substantially larger than the surface area of the monolithically integrated photodetector. In an exemplary embodiment, the surface area of the LED is approximately 1000×1000 μm² (or less) and the surface area of the integrated photodetector is approximately 100×100 μm² (or less). In some embodiments, the monolithically integrated photodetector is located in the corner, adjacent to and electrically separated from the LED, of the semiconductor platform that has a predetermined size in accordance with its target application. The shapes, dimensions, and relative positions of the LED and the photodetector on a given platform are determined based on the target application of the device and are not limited to the examples provided herein.

In the embodiment illustrated in part (a) of FIG. 4, the LED emits visible light of blue color; however, embodiments of the invention can also provide LEDs emitting monochromatic light of other colors when a voltage bias is applied. For example, embodiments of the invention are compatible with GaN-based LEDs grown on sapphire or bulk GaN substrates. The direct band gap of semiconductors comprising InGaN (from about 0.7 eV to about 3.4 eV) or AlGaN (from about 3.4 eV to about 6.2 eV) provide quantum wells that can cover a wide spectral range such as, for example, from approximately 200 nm to approximately 1770 nm, and the emission wavelength (i.e., color) can be tuned based on the composition of indium or aluminum. Part (a) of FIG. 4 is a microphotograph of an integrated LED-photodetector device emitting monochromatic blue light, while part (b) of FIG. 4 shows the device's corresponding electroluminescence spectrum according to an embodiment of the invention.

Due to the presence of stoke shift effect, there is a spectral difference between optical absorption and luminescence. For example, the absorption spectrum shown in part (b) of FIG. 4 indicates that the photodetector is able to respond to the shorter-wavelength-half of the LED emission spectrum. Part (a) of FIG. 5 shows that the photocurrent level measured when the LED was in operation at 10 mA is approximately four orders of magnitude higher than that measured under conditions of darkness, revealing that the integrated photodetector is capable of robustly responding to weak illumination intensity generated by the LED. This is advantageous because a key function of the on-chip photodetector is to monitor the variation in light intensity emitted by the LED. Part (b) of FIG. 5 shows the result of a device aging test revealing that the measured photocurrent can serve as reliable feedback signal for monitoring the intensity of the LED emission. Advantageously, embodiments of the integrated device provided herein enable both visible light emission from the LED and visible light detection by the photodetector integrated monolithically on the same platform.

In some embodiments, a lighting device can comprise a plurality of electronic devices each comprising an LED and a photodetector integrated onto the same semiconductor platform, and the current generated by the photodetector of each individual electronic device can be used to monitor the optical output of the LED on the same electronic device. The LED and the photodetector on a given electronic device can have the same semiconductor structure and can be fabricated monolithically via a single set of photolithography procedures. In some embodiments, the lighting device is a broadband LED light source.

In one embodiment, broadband LED emission is achieved by the use of phosphors for color down-conversion. Phosphorescent materials that emit light when exposed to certain wavelengths of radiation are used for color conversion in LEDs. As a device emits a higher-energy photon (i.e., shorter-wavelength), the phosphor absorbs it and then re-emits a lower-energy (i.e., longer-wavelength), and thus differently colored, photon. For white light emission, yellow, green, and/or red light-emitting phosphors may be used. Although the integration of phosphor materials requires the surface deposition of phosphor powder as well as an encapsulation layer, the sensing capability of the photodetector will remain unaffected due to the light coupling mechanism provided by the underlying transparent substrate (parts (a) and (b) of FIG. 6).

In another embodiment, broadband LED emission is achieved by mounting a plurality of LEDs, each integrated with a photodetector and capable of emitting the same or different visible light of primary colors (i.e., red, green, and blue) as the other LEDs, in a planar geometry (i.e., a multi-chip configuration) or a vertically stacked geometry (i.e., a chip-stacking configuration) into a single package. A chip-stacking configuration provides optimal color by stacking a blue LED onto a green LED, which is stacked on top of a red LED. The red LED structure can be an AlInGaP alloy grown on a GaAs substrate, in which case the substrate would not be transparent to the emitted light and the photodetector will rely entirely on sidewall absorption. Each of the three stacked LEDs can be individually controllable when arranged in the chip-stacking configuration. If all three are illuminated, an optically-mixed output can result in white light emission. Optical output of each individual LED can be readily monitored by its corresponding monolithically integrated photodetector. In a multi-chip approach, discrete blue, green, and red LEDs in a broadband lighting device can be driven individually and the intensity of various color components can thus be varied. Unlike the stacked configuration, the multi-chip configuration does not produce mixed colors and thus does not constitute a color-tunable lighting device. In an embodiment, lighting sources arranged in a multi-chip configuration or a chip-stacking configuration can be used to implement devices such as a full-color micro-display.

Exemplary embodiments of the integrated LED-photodetector devices and methods provided herein offer several advantages. First, on-chip functionality and reliability are improved with reduced packaging cost, achieved by eliminating hybrid optics and other supporting components. Second, the separation between the LED and the photodetector is minimized without intercepting LED emission, resulting in an ultra-compact device structure. Third, the on-chip photodetectors can better differentiate the intensity changes from individual LEDs than their off-chip counterparts. Fourth, the sensing capability of the photodetector remains unaffected by top-surface deposition of materials such as phosphor powder and/or an encapsulation layer as the photodetector relies on downward-travelling light signals from the adjacent LED.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

All patents, patent applications, provisional applications, and publications referred to or cited herein are incorporated by reference in their entirety, including all figures and tables, to the extent they are not inconsistent with the explicit teachings of this specification.

1. A light-emitting diode device, comprising:
a light-emitting diode, configured to emit light; and
a photodetector, configured to receive light emitted by the light-emitting diode and to generate a current corresponding to emission intensity of the light-emitting diode;
wherein the light-emitting diode and the photodetector are disposed in a same layer of the light-emitting diode device corresponding to a single semiconductor platform.

2. The light-emitting diode device according to claim 1, wherein the light-emitting diode and the photodetector have a same semiconductor structure.

3. The light-emitting diode device according to claim 1, wherein contact pads of the light-emitting diode and the photodetector are electrically isolated via trenches.

4. The light-emitting diode device according to claim 1, wherein the surface area of the light-emitting diode is larger than the surface area of the photodetector.

5. The light-emitting diode device according to claim 4, wherein the surface area of the light-emitting diode is at least ten times larger than the surface area of the photodetector.

6. The light-emitting diode device according to claim 1, wherein the light-emitting diode and the photodetector each comprise an n-type GaN layer, an active layer, and a p-type GaN layer.

7. The light-emitting diode device according to claim 1, wherein the light-emitting diode is configured to generate light in a spectral range between about 200 nm and about 1770 nm, and the photodetector is configured to detect light within a portion of the spectral range of the light-emitting diode.

8-28. (canceled)

29. The light-emitting diode device according to claim 1, further comprising:
a transparent substrate disposed below the light-emitting diode and the photodetector; and
a reflector, disposed below the transparent substrate;
wherein the photodetector is configured to receive light from the light-emitting diode transmitted through the transparent substrate and reflected by the reflector.

30. The light-emitting diode device according to claim 29, wherein the transparent substrate is a sapphire substrate.

31. The light-emitting diode device according to claim 29, wherein the photodetector is further configured to receive light from the light-emitting diode from above the photodetector.

32. The light-emitting diode device according to claim 29, wherein the reflector is a reflective coating.

33. The light-emitting diode device according to claim 29, wherein the reflector comprises silver, aluminum, or a distributed Bragg reflector (DBR).

34. The light-emitting diode device according to claim 1, further comprising:
a current spreading layer disposed above the light-emitting diode and the photodetector.

35. The light-emitting diode device according to claim 1, wherein the light-emitting diode device is part of a display.

36. A device, comprising a plurality of light-emitting diode devices, wherein each light-emitting diode device comprises:
a light-emitting diode, configured to emit light; and
a photodetector, configured to receive light emitted by the light-emitting diode and to generate a current corresponding to emission intensity of the light-emitting diode;
wherein the light-emitting diode and the photodetector are disposed in a same layer of the light-emitting diode device corresponding to a single semiconductor platform.

37. The device according to claim 36, wherein the device is a display.

38. The device according to claim 36, wherein each light-emitting diode device of the plurality of light-emitting diode devices is individually controlled.

39. The device according to claim 36, wherein each light-emitting diode device of the plurality of light-emitting diode devices is configured to emit light of a same spectral range as light emitted from all other light-emitting diode devices of the plurality of light-emitting diode devices.

40. The device according to claim 36, wherein at least two light-emitting diode devices of the plurality of electronic devices are configured to emit light of different spectral ranges.

41. The device according to claim 36, wherein the plurality of light-emitting diode devices are mounted onto a single package in a side-by-side configuration.

42. The device according to claim 36, wherein the plurality of light-emitting diode devices are mounted onto a single package in a vertically stacked configuration.

43. The device according to claim 36, wherein each light-emitting diode device further comprises:
a transparent substrate disposed below the light-emitting diode and the photodetector; and
a reflector, disposed below the transparent substrate;
wherein the photodetector is configured to receive light from the light-emitting diode transmitted through the transparent substrate and reflected by the reflector.

44. The device according to claim 43, wherein the transparent substrate is a sapphire substrate.

45. A method of fabricating a light-emitting diode device, the method comprising:
depositing an n-type semiconductor layer on a top surface of a substrate;
depositing an active layer on the n-type semiconductor layer, the active layer comprising a plurality of quantum wells;
depositing a p-type semiconductor layer on the active layer;
etching the n-type semiconductor, active, and p-type semiconductor layers to form trenches between a light-emitting diode and a photodetector, wherein the light-emitting diode and the photodetector are electrically isolated from one another by the trenches.
